(19) United States
(12) Patent Application Publication
(10) Pub. No.: US 2015/0331038 A1
(43) Pub. Date: Nov. 19, 2015

(54) ANALYSIS SYSTEM

(71) Applicant: Radiation Monitoring Devices, Inc., Watertown, MA (US)

(72) Inventors: Evan Weststrate, Newton, MA (US); Noa M. Rensing, West Newton, MA (US); Timothy C. Tiernan, Newton, MA (US)

(73) Assignee: Radiation Monitoring Devices, Inc., Watertown, MA (US)

(21) Appl. No.: 14/495,116

(22) Filed: Sep. 24, 2014

Related U.S. Application Data
(60) Provisional application No. 61/884,908, filed on Sep. 30, 2013.

(51) Int. Cl. G01R 31/28

(52) U.S. Cl. CPC G01R 31/2834

(57) ABSTRACT

An analysis system for analyzing circuits and other appropriate devices as well as its method of use are disclosed. In one embodiment, a system may include one or more electromagnetic field generators configured to generate an electromagnetic field proximate to a circuit. The system may also include one or more electromagnetic field sensors configured to scan the circuit by detecting an electromagnetic field induced in the circuit. An associated computing device may be configured to receive the scan of the circuit and compare the scan to a reference scan of the circuit to determine whether the circuit is different from the reference scan.

### CROSS-REFERENCE TO RELATED APPLICATIONS

This application claims the benefit under 35 U.S.C. §119(e) of U.S. provisional application Ser. No. 61/884,908 filed Sep. 30, 2013, the disclosure of which is incorporated by reference in its entirety.

### GOVERNMENT LICENSE RIGHTS

This invention was made with government support under M67854-08-C-6537 awarded by the USMC. The government has certain rights in the invention.

### FIELD

Disclosed embodiments are related to analysis systems and their methods of use.

### BACKGROUND

Electronic hardware maintenance and component tracking is an issue that faces both civilian and military entities. Additionally, a number of different systems have been implemented to try and aid with these processes. Currently, when a piece of military electronics hardware is discovered to be malfunctioning, a group that has the hardware fills out an Equipment Repair Order (ERO) which documents the electronics hardware's progress through a repair cycle. This repair cycle may require multiple ERO's as well as multiple transfers of components and subcomponents between maintenance depots, intermediate repair centers, off-site repair centers, supply and management systems, and other entities in order to repair the original device, recover and/or repair nonfunctional subcomponents, and manage inventories

### SUMMARY

In one embodiment, a system includes one or more electromagnetic field generators configured to generate an electromagnetic field proximate to an electronic circuit. The system also includes one or more electromagnetic field sensors configured to scan the circuit by detecting an electromagnetic field induced in the circuit. A computing device is configured to receive data from the scan of the circuit and compare the data to a reference scan of the circuit to determine whether the circuit is different from the reference circuit scan. In some cases the circuitry under test is compared to a gold standard circuit. In others it is compared to electronic signals typical of electronic components and/or the particular circuit under test. The circuit may be powered or unpowered during inspection and maintenance.

In another embodiment, a system includes an electromagnetic field generator configured to generate an electromagnetic field proximate to a circuit to induce an electromagnetic field in a conductive portion of the circuit. The system also includes an electromagnetic field sensor configured to scan the circuit by detecting the induced electromagnetic field. An imaging device is configured to image the signals in the circuit detected by the sensor at each point in the circuit, and a computing device is configured to receive the image of the circuit from the imaging device. The computing device is also configured to compare the image to a reference image to identify the circuit.

In yet another embodiment, a method includes: generating an electromagnetic field proximate to a circuit to induce an electromagnetic field in a conductive portion of the circuit; scanning the circuit by detecting the induced electromagnetic field; and comparing the scan to a reference scan of the circuit to determine whether the circuit is different from the reference scan.

In another embodiment, a method includes: an electromagnetic field generator configured to generate an electromagnetic field proximate to a circuit to induce an electromagnetic field in a conductive portion of the circuit; generating an electromagnetic field proximate to a circuit to induce an electromagnetic field in a conductive portion of the circuit; scanning the circuit by detecting the induced electromagnetic field; imaging the circuit; and comparing the image to a reference image to identify the circuit.

It should be appreciated that the foregoing concepts, and additional concepts discussed below, may be arranged in any suitable combination, as the present disclosure is not limited in this respect. Further, other advantages and novel features of the present disclosure will become apparent from the following detailed description of various non-limiting embodiments when considered in conjunction with the accompanying figures.

In cases where the present specification and a document incorporated by reference include conflicting and/or inconsistent disclosure, the present specification shall control.

### BRIEF DESCRIPTION OF DRAWINGS

The accompanying drawings are not intended to be drawn to scale. In the drawings, each identical or nearly identical component that is illustrated in various figures may be represented by a like numeral. For purposes of clarity, not every component may be labeled in every drawing. In the drawings:

FIG. 1A is a photograph of a an analysis system for circuit testing;

FIG. 1B is a photograph of a robotic prober adapted to include a non-contact, electromagnetic sensor for functioning as an analysis system for circuit testing;

FIG. 2 is a schematic representation of an unpowered printed circuit board and a scan of a faulty circuit compared to a reference scan;

FIG. 3 is a photograph of a probe antenna for generating and receiving electromagnetic signals attached to a moving head of a robot for scanning a printed circuit board;

FIG. 4 is a photograph of a printed circuit board including a chip mounted antenna;

FIG. 5A is a front view of a printed circuit board including an introduced fault;

FIG. 5B is a back view of the printed circuit board of FIG. 5A;

FIG. 6A is a photograph of the printed circuit board of FIG. 5A being tested;

FIG. 6B depicts an overlay of a measurement grid with the front view of the printed circuit board of FIG. 5A;

FIGS. 7A-7D present three-dimensional graphs of the average scan results for three functional printed circuit boards;

FIGS. 8A-8D present three-dimensional graphs of the scan results of the printed circuit board including an introduced fault depicted in FIG. 5 compared to the average scans of functional printed circuit boards presented in FIGS. 7A-7D;

FIG. 9 is a graph of the difference between the scans of a printed circuit board without a fault and with a fault from FIGS. 7A-8D;

FIG. 10 is a schematic representation of the difference between a scan of a printed circuit board with and without a fault overlaid with the printed circuit board including the detected fault;

FIG. 11 is a photograph of a radiofrequency probe system for scanning the printed circuit board;

FIG. 12 is a photograph of the radiofrequency probe system of FIG. 11 scanning a printed circuit board;

FIG. 13 is a photograph of the radiofrequency probe head of FIG. 11;

FIGS. 14A-14D are graphs of the reflection coefficient scan data for circuit card assemblies;

FIG. 15A is a graph of the reflection coefficient scan data of a circuit card assembly showing higher variations where through hole pins are located;

FIG. 15B is a graph of the reflection coefficient scan date of a circuit card assembly showing variations due to components made by different manufacturers;

FIG. 16A is a photograph of through hole pins located in a circuit card assembly from a first manufacturer;

FIG. 16B is a photograph of a switch of the circuit card assembly of FIG. 16A;

FIG. 17A is a photograph of through hole pins located in circuit card assembly from a second manufacturer;

FIG. 17B is a photograph of a switch of the circuit card assembly of FIG. 17A;

FIG. 18A is a photograph of a circuit card assembly including a faulty transformer coil;

FIGS. 18B-18E are graphs of the reflection coefficient scan data for the circuit card assembly of FIG. 18A including a faulty transformer coil;

FIG. 19 is a schematic representation of a monopole antenna simulation model; and

FIG. 20 is a graph of the reflection coefficient for different Y positions.

### DETAILED DESCRIPTION

The inventors have recognized the benefits associated with an analysis system capable of facilitating the diagnosis and repair of various types of circuits, or devices, through the use of a non-destructive scanner capable of obtaining the desired information needed for a repair. In some embodiments, such a system may also include an optical imaging/scanning capability and/or a standoff nodal analyzer with one or more sensors configured for scanning a circuit or device. In some embodiments, the system may also be automatically positioned using any appropriate method including robotic control, though manual operation is also possible.

Depending on the embodiment, a database may help to automate portions of the operation of an analysis system. For example, in some embodiments, an optical scanning system and database may be used to take an image of a circuit card assembly, or other device, which is subsequently identified using previously scanned images of the same type of device stored in the database. The system may then conduct a scan of the device and compare it to a previous scan of a functional device stored in the database to determine which component is faulty. This information may be used to assist in tracking the component as it moves through a repair cycle which may help to facilitate automated entry of data into a corresponding intelligent database. The intelligent database may be used to perform statistical analysis to determine the most likely cause of faults in particular circuit or device. Thus, as the database grows, it should be possible to perform prognostics based on factors such as age and use of a device such as a circuit card assembly to determine the most likely cause of failure in a particular device. The testing sequence may then be optimized by testing the various components according to the order of which component is most likely to have caused the failure.

Depending on the embodiment, the scanning capability may be provided by one or more sensors that perform stand-off measurements. The standoff sensing capability may allow the analysis of signals and the isolation of defects at the nodes of a circuit card assembly. As described in more detail below, the sensor may be positioned using manual control or an automated control, such as any applicable robotic control.

For the purposes of this application, the analysis systems described are described relative to testing of a circuit, such as a circuit card assembly. However, it should be understood that the analysis systems described herein may be applied to other applicable devices as well and are not limited to only testing and analysis of circuits as the disclosure is not so limited.

In one specific embodiment, an analysis system includes one or more electromagnetic field generators that are configured to generate an electromagnetic field proximate to a circuit, or other device. The generated electromagnetic field may induce a corresponding electromagnetic field in the conductive portions of the circuit or device. These induced electromagnetic fields may then be sensed using one or more electromagnetic or magnetic field sensors configured to scan the circuit or device by detecting the induced electromagnetic field. The scanning system may scan a circuit or device through the use of an appropriate translation system associated with a scanning head. The translation system is configured to translate the one or more electromagnetic field sensors relative to the circuit, or other device, in any appropriate direction in order to scan the circuit. These directions may be located in one, two, or three dimensions, as the disclosure is not limited to any particular direction or orientation of scanning. This may be accomplished in any appropriate manner including for example, an H-frame, a gantry system, a robotic arm, or any other appropriate system.

In addition to magnetic sensing, electric field measurements for standoff detection of signals in circuits, such as circuit card assemblies, and other appropriate devices, may be used in some embodiments. For example, in low-power digital circuitry, such as CMOS integrated circuits, the currents associated with operation are very small and can be difficult to detect with a magnetic sensor. However, electric fields are larger and can be detected with a properly designed electric field sensor (capacitance sensor). Therefore, it may be possible to measure both magnetic fields and electric fields within an operating circuit using a thin-film anisotropic magnetoresistance (AMR) sensor. It may also be possible to use a spherical sensor not made with AMR material for the detection of electric fields because the spherical sensor does not exhibit directionality and may also be cheaper and easier to fabricate.

After scanning a device, or a portion of the device, such as a circuit card assembly and its subcomponents, the scan may be compared to a corresponding reference scan. Differences between the current scan and the reference scan may be indicative of a fault, defect, type of component, or other appropriate information regarding the scanned circuit or device. The differences between the scans may be determined using a computing device configured to receive a scan of the circuit from associated electromagnetic and/or magnetic field sensors. After receiving the scan, the computing device may compare the scan to the reference scan to identify the differences between the scans. The identified differences might correspond to a magnitude of an induced electromagnetic field, a real component of an induced electromagnetic fields, an imaginary component of an induced electromagnetic field, and a phase difference of the electromagnetic field to name a few. In addition to identifying differences between the scan and the reference scan, the computing device may also generate an IN curve for the scanned circuit.

Depending on the particular embodiment, a computing device may analyze the differences between a scan and a reference scan in any appropriate fashion. For example, in one embodiment, the computing device may deconvolve the scan and/or reference scan with the point spread function of a set of magnetic field sensors. Alternatively, in another embodiment, the computing device may deconvolve the scan and/or reference scan in the spatial domain and/or the Fourier domain. In yet another embodiment, the computing device may be associated with a phase detector configured to detect a plurality of phase differences between an applied magnetic field and an induced magnetic field which may be used to determine information about a plurality of conductive layers of a circuit disposed at different circuit depths as well as determining the depths of these circuits from the phase differences. In another embodiment, the computing device may determine the heights of defects in the conductors based on three dimensional scans of the magnetic fields.

It should be understood that a computing device may correspond to any appropriate device capable of analyzing the differences between a scan from the one or more sensors and a reference scan. Appropriate computing devices include, but are not limited to, a computer processor, a distributed computing network, a remotely located server, an externally connected computer, or any other appropriate device as the disclosure is not so limited. Additionally, it should be understood that the computing device may either be integrated with the analysis system or it may be located externally, and even possibly remotely, from the analysis system depending on the particular embodiment.

In some embodiments the reference scan may be located in a database in electrical communication with a computing device. The database may be located locally on the same system, another portion of a network, a remotely located server, or any other appropriate location. Additionally, the reference scan may either correspond to a signal scan of a functional device, or it may be an average of multiple devices, as the disclosure is not so limited. In some applications, a reference scan may be referred to as a “gold standard”. When used, a computing device may retrieve the reference scan from the database for use in analyzing a scanned circuit or device.

In order to identify the type of fault or defect present within a circuit, in some embodiments, a database may also include scans of circuits or devices including known faults. In such an embodiment, the computing device may compare the scan to the reference scans of known faults to identify what is wrong with a particular device or component.

In some instances, it may be desirable to display information regarding a circuit or device being analyzed to a technician or other appropriate user. In such an embodiment, an appropriate indication of the detected circuit status, such as a fault in a particular component, may be output to a display for viewing by a user. Appropriate displays include, but are not limited to: printouts; monitors; handheld devices such as tablets and smartphones; and/or any other appropriate device capable of displaying the information to a user. The output information may simply correspond to an error code or it may provide a visual indication overlaid with some representative figure of the circuit or device. In one such an embodiment, a horizontal and vertical position of a fault determined from the scans by the computing device may be overlaid with an appropriate representative image of a circuit the circuit or device. For example, an indication of a fault (e.g. coloration, circling, etc. . . . ) may be overlaid with an image of the device, a circuit layout, a design specification, a design layout, a conductor map, and/or any other appropriate image. In certain embodiments, the indication of a fault may correspond to a difference between a current scan and a reference scan overlaid with an image of the circuit or device being analyzed. In embodiments where the indication of a fault i is overlaid with a corresponding image, these first and second images may be appropriately scaled such that they are substantially matched.

In some embodiments, it may be desirable to use information from a database regarding how often particular repairs are made to a circuit or device. This information may either be preprogrammed into a database, or it may be compiled from statistical analysis of data entries associated with the repair of devices. In either case, the information may include a list of the parts or components on a particular circuit or device that are most likely fail. For an automated process, the system may automatically test those parts or components first. Alternatively, when implemented with a manual process, the system may prompt a user or technician to test the components or parts most likely to fail first prior to testing other components or parts. In either case, this may help to make the testing more efficient, faster, and less costly.

In some embodiments, it may also be desirable for an analysis system to automatically identify the circuit board device being analyzed. In such an embodiment, the analysis system may include an appropriate imaging device such as an optical camera capable of taking an image of a circuit or device being analyzed and outputting it to an associated computing device. In such an embodiment, a database associated with the computing device may include reference images of one or more circuits or devices that the system is intended to analyze. Once an image of the circuit or device has been taken, the computing device may compare the image of the circuit or device being analyzed to a reference image present in the database to identify the type of circuit, or device, currently being analyzed. The computing device may then retrieve the appropriate reference scan, or scans, from the database for analyzing scans of the circuit or device.

The presently described analysis systems may incorporate any appropriate sensor capable of detecting a desired fault in a particular circuit or device of interest. For example, in one embodiment, a sensor may include one or more electro-magnetic field sensors including an antenna. In another embodiment, the electromagnetic field sensor may be electromagnetic field generator. Examples of appropriate sensors include, but are not limited to, acSQUID magnetometer, a Fluxgate, a Hall effect sensor, magnetostrictive material, and/or a magneto-resistive element. In addition to the above, the one or more sensors of the analysis system may include one or more magnetic field sensors and/or one or more electric field sensors which may or may not be integrated into a single sensor. For example, an anisotropic magnetoresistance (AMR) sensor may be used to measure both magnetic and electric fields which make it possible to detect the dynamic performance of integrated circuits and components during the operation of a circuit.

The above noted sensors may be arranged in any appropriate number and/or configuration. For example, in one embodiment, a single sensor is used. Alternatively, in some embodiments, a plurality of sensors arranged in an array of sensors may be used. Such an embodiment may increase the sensitivity and scanning speed of a system by providing more sensors over a larger area with a smaller resolution.

When an analysis system is finished testing a particular circuit or device it may be desirable to automatically update an associated database. In such an embodiment, the analysis system may automatically enter the test results, failure modes, list of broken parts, and/or generate or update work forms into a database. Such an embodiment may help to reduce the manual labor and confusion associated with tracking repairs of various devices and components. Additionally, each time a circuit or device is tested, the database becomes more complete regarding the various types of failure modes and frequencies with which repairs are observed for a given device. This may be used to both optimize the testing process, as noted above, as well as help to manage workflows and stocks.

The currently described analysis systems may be used in any appropriate application. For example, these systems might be used for: automated testing of circuitry; identification of defective parts in malfunctioning circuit boards such as circuit wafers and ball grid arrays; eddy current measurements related to circuitry and other conductive materials; machine vision for inspection of circuitry and electronic components during manufacturing and quality assurance; and manufacturing defect analysis for inspection of printed circuit boards during manufacturing to name a few.

Turning now to the figures several non-limiting embodiments and examples are described in more detail. It should be understood that while particular embodiments depicted in the figures may or may not include a specific component, feature, or method of operation, it should be understood that the various components, features, and methods of operations described herein may be interchanged and combined with one another without limitation as the disclosure is not so limited.

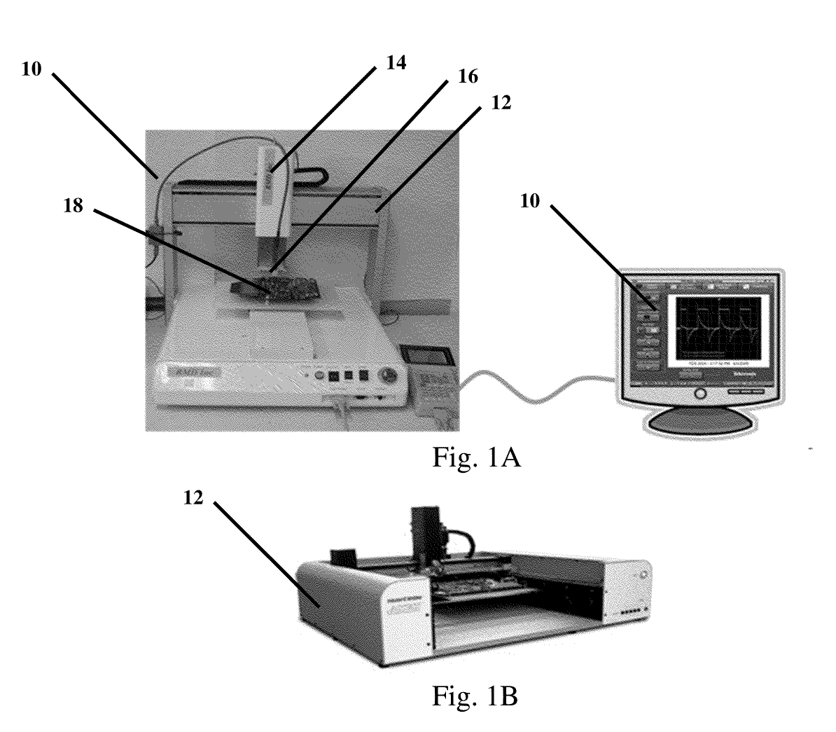

FIG. 1A shows an analysis system 10. In the depicted embodiment, the system includes a translation system 12 configured to move an associated scanner 14 in a two-dimensional plane parallel to the device being scanned. However, embodiments in which the scanner 14 may be moved in three dimensions are also contemplated. The scanner 14 includes an electromagnetic field generator and electromagnetic field sensor as described above though alternative scanner heads are also contemplated. As depicted in figure, the circuit card assembly 18 is positioned proximate to the scanner head 16 for subsequent scanning analysis. While a circuit card assembly has been depicted, it should be understood that any other appropriate device may be analyzed using the analysis system. The scanner and translation system are in electrical communication with an appropriate computing device 20 which is configured to control the translation system and scanner to scan the circuit card assembly. In some instances, the computing device may also include a display for presenting outputs to a user. During use, the analysis system might be used to move the sensor into close proximity with a desired component such as a pin, integrated circuit, or lead of a device being tested.

FIG. 1B shows an example of a translation system 12 which may be integrated into an analysis system. In the depicted embodiment, the translation system is a commercially available robotic prober that includes an integrated sensor capable of being moved along three separate axes in three directions. In such an embodiment, the combination of a translation system and sensor may be used to perform dynamic measurements of circuit components.

Example: RAFTS Testing Method

Testing was performed for a Radiating Antenna Fault Test System (RAFTS) and its application to non-contact/non-operating test of a circuit card assembly (CCA).

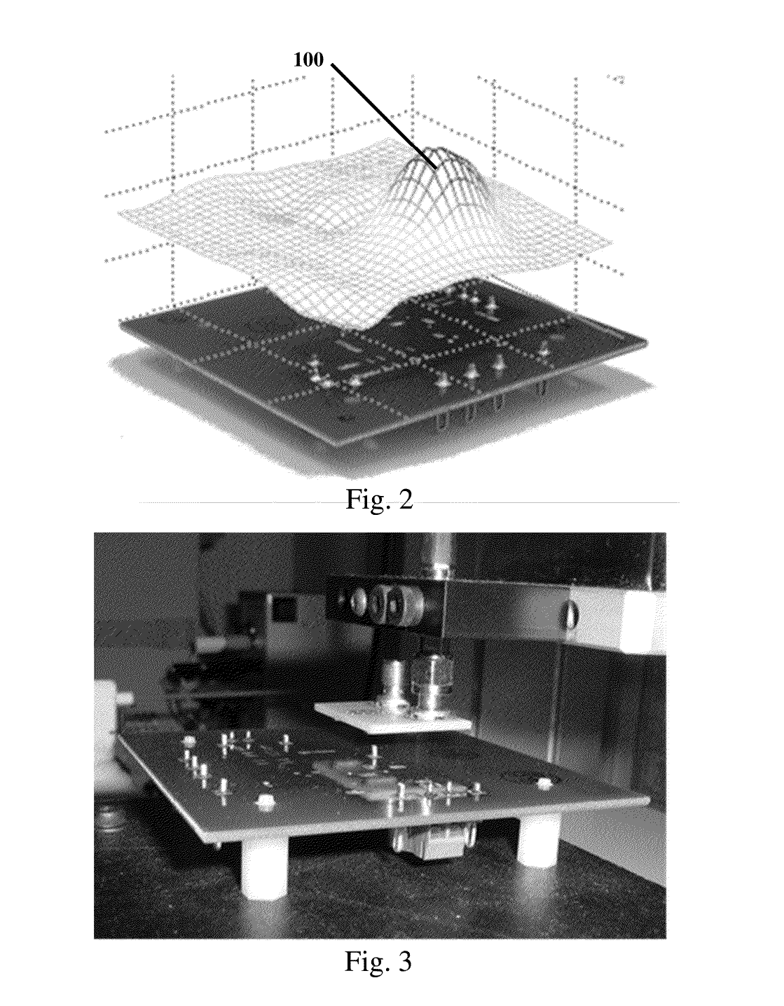

The experimental setup included a GHz Vector Network Analyzer running frequency sweeps in the 5-6 GHz range to a custom designed antenna probe. The antenna probe was scanned over the surface of the CCA under test and the variations in the complex reflection coefficient (Γ) was studied in an attempt to distinguish faults and their locations based on a gold standard comparison with the average of multiple scans of functional devices. To better control the experiment and to make test iterations less complicated, off the shelf, well documented, development circuit boards that were readily available were used. This enabled the modification of the circuits in a known way to simulate faults and make repeatable measurements under known circumstances. FIG. 2 shows the response of an unpowered circuit component to a RAFTS probe showing an anomaly 100 compared to a gold standard scan.

Example: Scan Setup

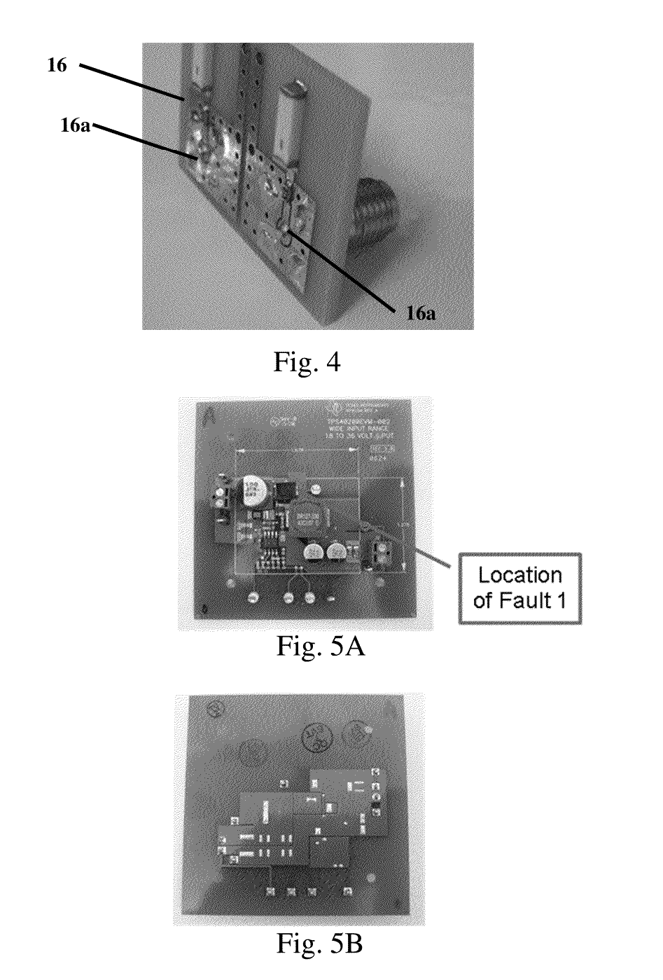

An x-y-z positioning robot was used to position and move a probe antenna near various part of a CCA under test. The probe antenna was affixed to the moving head of the robot so that it could be situated close to the board without actually touching, see FIG. 4. In order to bring the RAFTS antenna probe as close as possible to the CCA, the bottom side of the board was scanned.

Several operational configurations were considered for the scanner, including a transmitting/receiving antenna pair fixed to the robot fixture head, a transmitter at the robot head and receiver in a fixed position, perpendicular to the board or parallel mounting of the antenna, and scanning of the component side versus bottom side opposite the components of a CCA. While any appropriate configuration might be used, in one embodiment, a single transmission antenna 16a may be mounted parallel to the surface to take advantage of an effective transmitting axis of the chip antenna, see FIG. 4.

For the current experiments, a printed circuit board was designed and built to mount a chip antenna designed to resonant at approximately 5.7 GHz, see FIG. 4. When operating near this resonance, the wavelength in air would be about 50 mm. Given that the reactive near field is typically considered the area within about λ/2π of an antenna, small circuit topology features and changes on the order of 8 mm should be discernible meaning that the probe has a spatial resolution near this value. The depicted probe circuit including two antennas was designed to be operated as a transmit/receive pair, but in the test discussed here, only one antenna was actively connected. The antenna layout followed best design considerations to match the open-air impedance to 50Ω. Without wishing to be bound by theory the idea was that by bringing circuit features close to this probe, the antenna's impedance would be affected in different ways by the various conductive, semi-conductive, capacitive, inductive, and non-linear components proximate to it. In this way, the system could detect the differences between an unpowered gold standard CCA (good board) and an unpowered CCA with a fault, and know the location of the fault to within about 8 mm making it easy to identify the faulty component.

Example: Circuit Card Testing

The circuit board used was a simple bucking power supply demonstration circuit measuring approximately 2 inches by 2 inches. The boards could be easily modified to create artificial faults for comparison scans. Three individual, identical boards were used, but there were slight variations in the solder and component placements due to hand assembly of the boards. The fault introduced in this experiment was a break in the electrical connection of the cathode connection on the primary rectifying diode. The fault could be made or broken easily. FIGS. 5A and 5B shows the test PCB used as well as the location of the fault used to evaluate the functionality of the sensor and inspection concept.

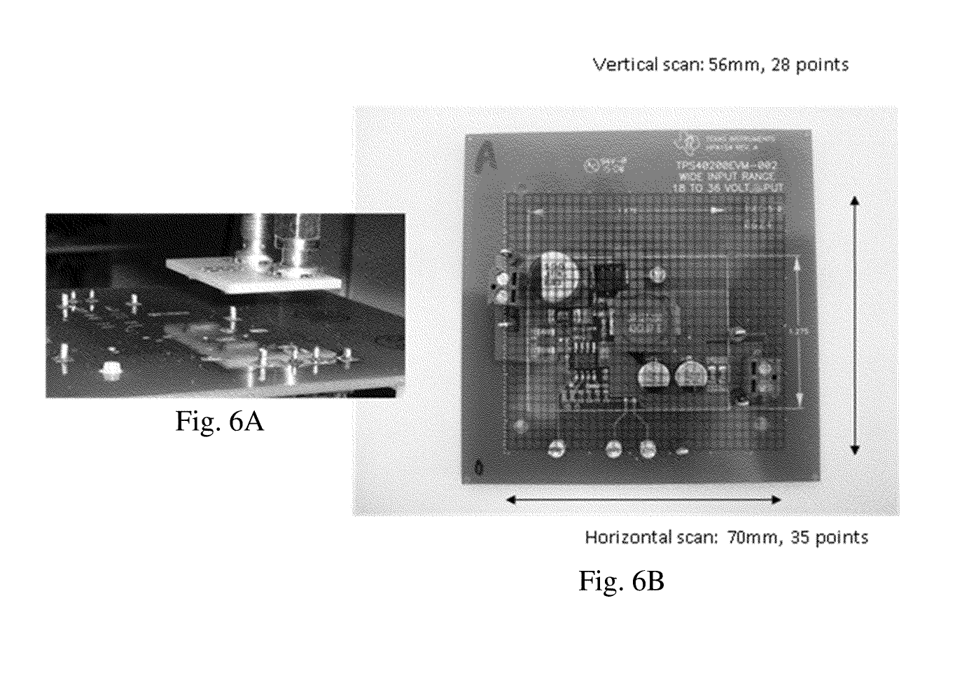

The scan area is shown as viewed from the top side of the board. The mesh point spacing was 2 mm in each of the X and Y directions, see FIGS. 6A and 6B. Data captured at each mesh point was the reflection coefficient (Γ) of the antenna located at the center positioned above each mesh point. Γ is a complex quantity representing how much signal is reflected back to the source due to the antenna's mismatch to the cable or feed line's characteristic impedance. If the Γ were zero, that would represent perfect matching and no reflection. If |Γ| were 1, that would represent 100% reflection (as in an open or closed circuit termination). Perfect matching is not expected even though the chip antenna was designed to be 50Ω at the resonant frequency.

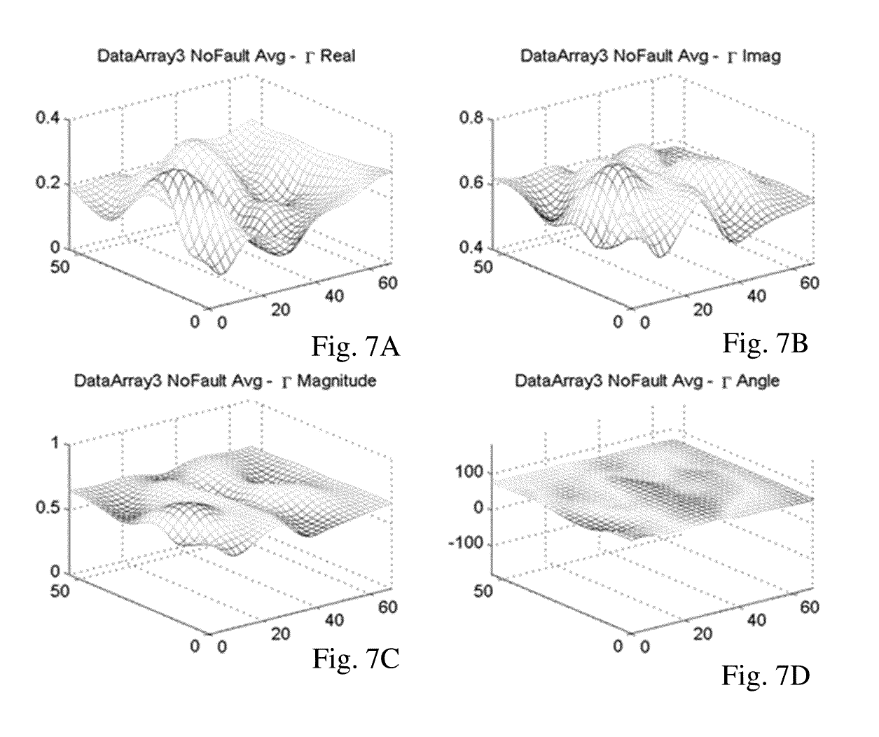

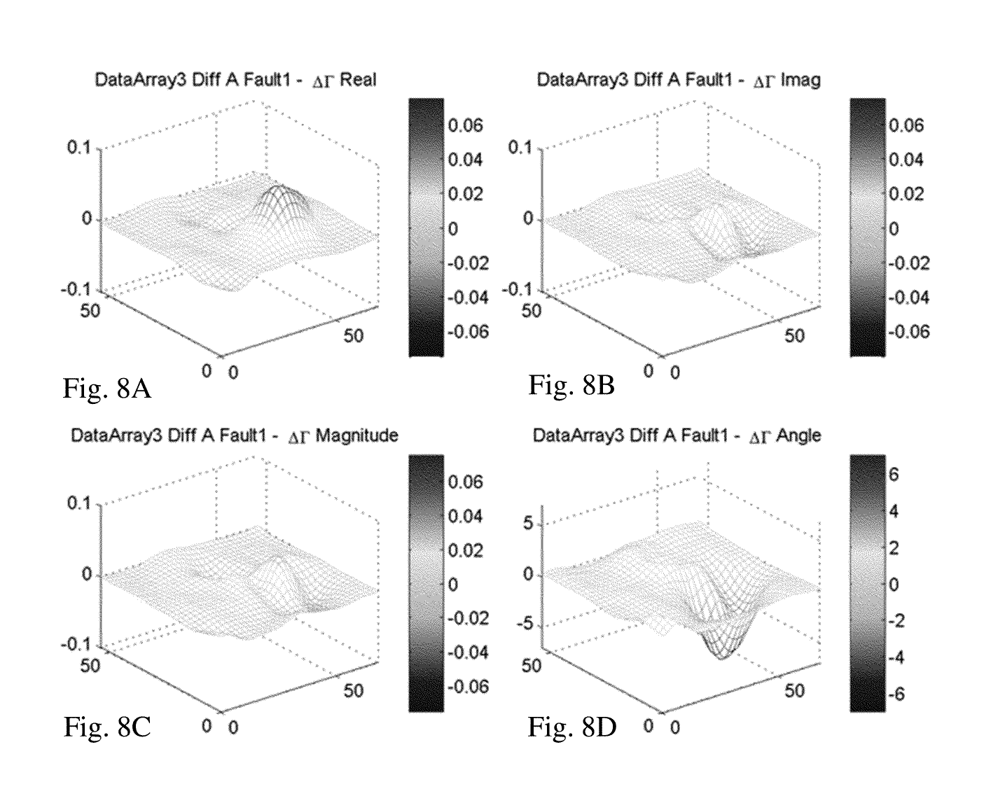

In order to present the complex data over a scan area, both real/imaginary and magnitude/phase plots with an XY-Z mesh (where X and Y are the position and Z is the measurement value) are presented. The first plot set is an average of scans of three boards with no faults to show the raw data that would form the baseline for a gold standard PCB or CCA, see FIGS. 7A-7D. It is expected that a good board would have a scan that is very similar to theses scans and a broken PCB would show a significant difference. The second plot set shows the difference between board A (with fault) and the average of the scan values without a fault, see FIGS. 8A-8D. To determine the differences between the current scan and the reference scan, the scan from each parameter was subtracted from the average of the three scans made for the averaged gold standard PCBs. If the PCB had no faults there would be very little difference between the scans. However, with the broken PCB a significant difference in the difference plot is observed, and the location of the difference pinpoints the broken component. Having four parameters to measure provides sufficient data to reduce the possibility of false positives.

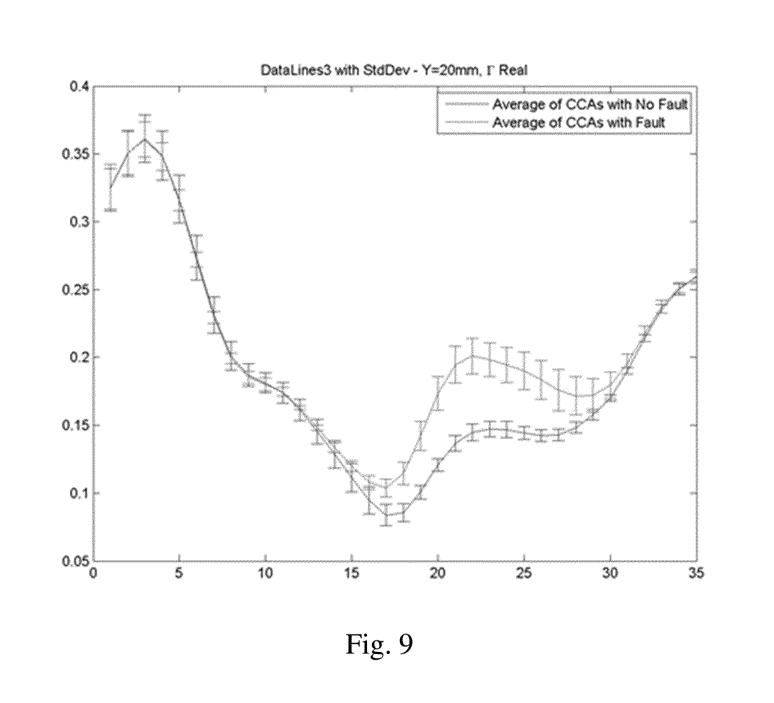

To evaluate the repeatability of the scan data, the results of multiple identical circuit boards having the same fault were compared. In this experiment, each CCA was given the same fault, scanned, and the results averaged for three faulty CCAs and compared to the results of the average scan for three good CCAs. The plot in FIG. 9 shows one line (y=20 mm) where the data differs between the Faulted and No Faulted CCAs. The variation in CCA parameters with no fault is small as is the variation in CCAs with a fault (standard deviation for three scans marked with bars). However the difference in the average response of the probe between the good and defective CCAs is greater than the standard deviation of the variation among the CCC in each population. This indicates that this scanning technique can be used to differentiate the good and bad CCAs with statistical relevance. In addition, there are 28 lines of data in each scan (in addition to the one shown in this plot) and additional data should increase the probability of detection and reduce the probability of false positives.

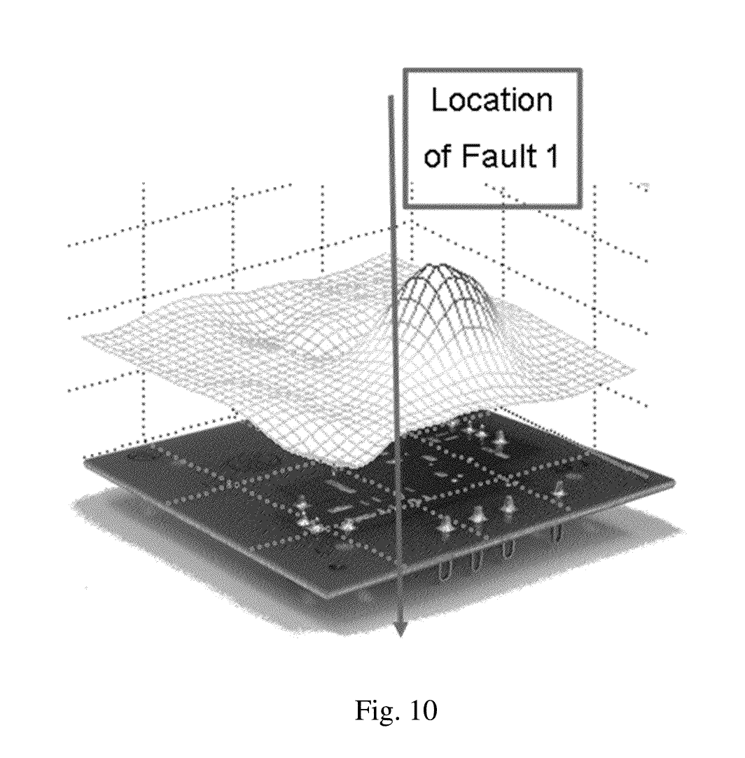

FIG. 10 is an overlay of the difference plot for board A with a fault. The peak shows where there is a large difference in the measurement from the ‘gold’ standard. The large peak does not occur right at the fault location, but it is still obvious. Without wishing to be bound by theory, this discrepancy is likely due to several reasons. First, the antenna probe is large compared to small components and covers a significant area, therefore it is probably sensitive to conductive objects not just near the center of the chip antenna. The feed point from the cable fixture is also likely sensitive to conductive features nearby. Additionally, the fault introduced may not ‘look’ like anything different right near the fault, rather it may show effects on a different section of the CCA. This may be a big factor if ground planes are present and the fault is on the opposite side of the plane. In either case, discrepancies and faults detected during a scan may be correlated with particular components on a circuit or other device and may be readily determined through experimentations with antenna type, geometry, and positioning.

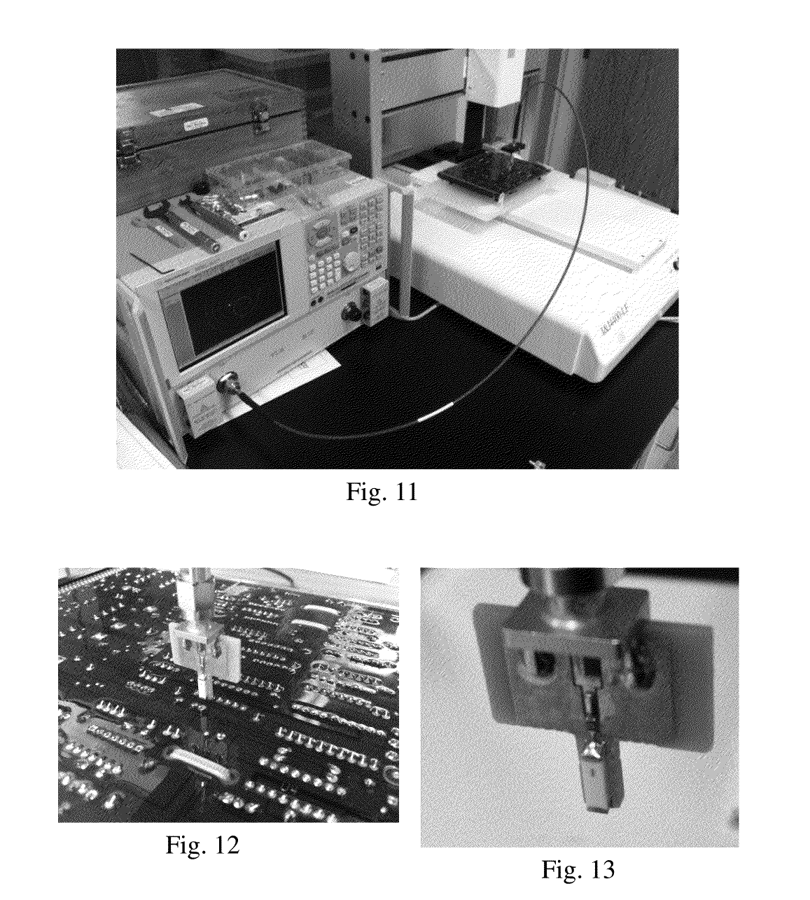

A radiofrequency probe shown in FIGS. 11-13 was designed with a small ground plane and a feeder trace connecting the signal cable to a standard 5 GHz tuned chip antenna. The antenna as laid out, was matched to 50-Ohms impedance in free space at approximately 5 GHz. We found that that slightly changes when scanning near a ground plane. The probe is depicted as being used for scanning the backside of a circuit card assembly. A close-up of the probe head is also shown. Depending on the features that were being examined, choosing a different frequency slightly above or below 5 GHz worked well. Without wishing to be bound by theory, it is believed that the frequency for examining a particular defect will vary from component to component and from defect to defect.

It should be understood that any number of modifications of the above noted probes are possible. For example, different antenna layout, feed line geometries from the connector to the chip antenna, and even positioning features as close to the CCA under test as the antenna itself might affect the sensitive of the sensor to circuit topology changes just as much as or more than the antenna near field is sensitive. Additionally, frequencies both greater than and less than those noted above might be used to alter the effects of the reactive near field which may help improve the effectiveness of the localization of the fault.

Example: Average Scan

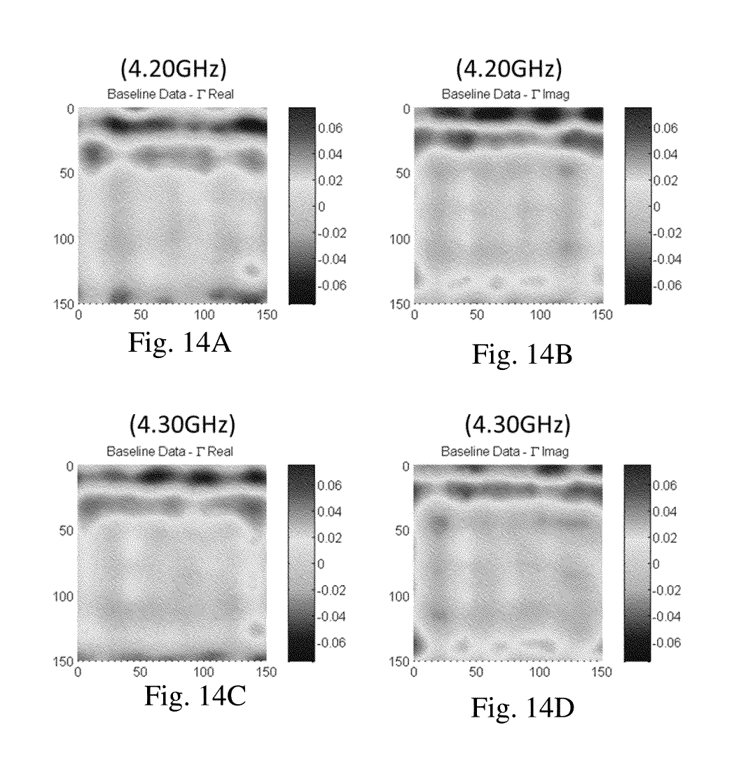

FIGS. 14A-14D are graphs of the reflection coefficient scan data for four different circuit card assemblies of the same design.

Example: Identifying Features and Manufacturer Variations

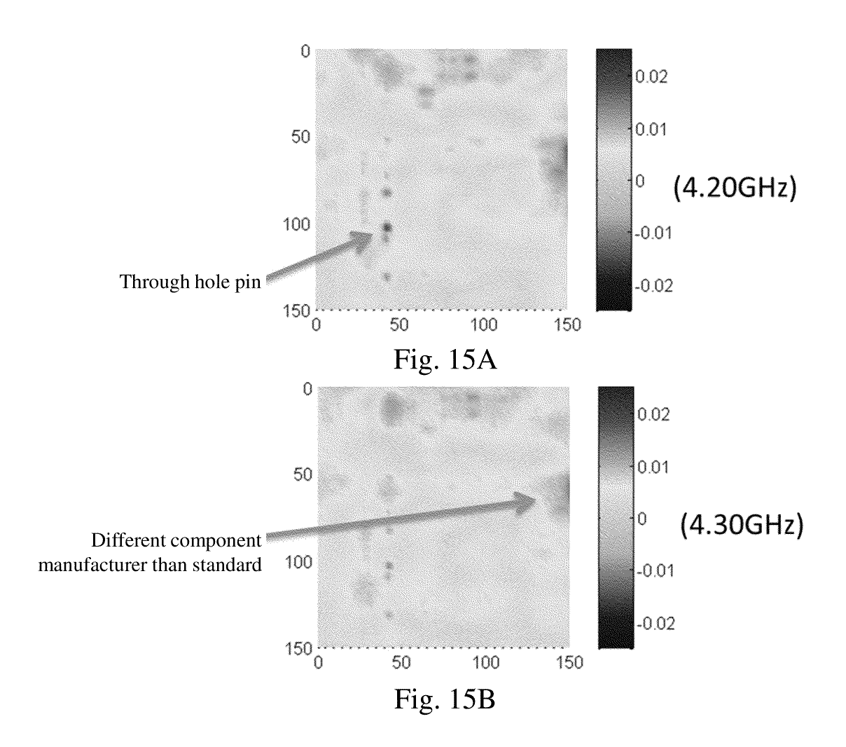

FIG. 15A is a graph of the reflection coefficient scan data of a circuit card assembly showing higher variations where through hole pins are located. Specifically, large variations can be seen where the through-hole pins stand proud from the circuit board. Without wishing to be bound by theory, this may be due to the scanner scanning over these features with little clearance. Therefore, this structural variation shows up as a relatively large difference in the reflection coefficient.

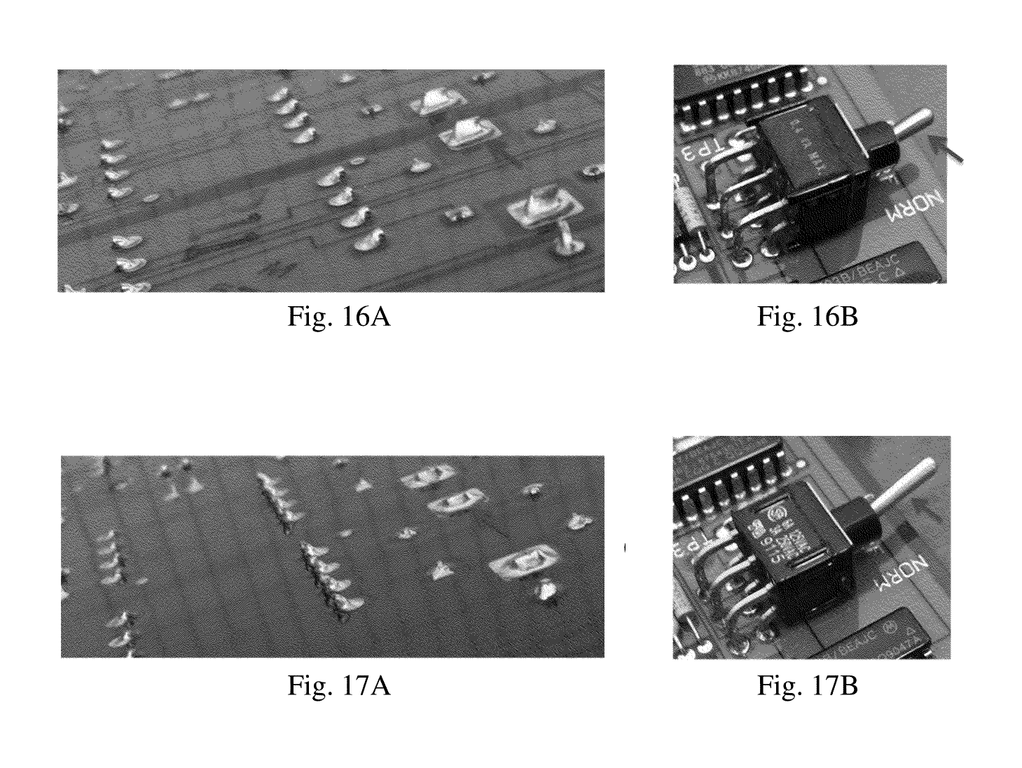

FIG. 15B is a graph of the reflection coefficient scan date of a circuit card assembly showing variations due to components made by different manufacturers. The variations may be due to the use of possibly different internal structures. For example, this may be caused by different through-hole pin sizes and switch arms with different lengths as shown in the circuit card assemblies shown in FIGS. 16A and 16B versus 17A and 17B which are made by different manufacturers.

Example: Identifying a Faulty Transformer Coil

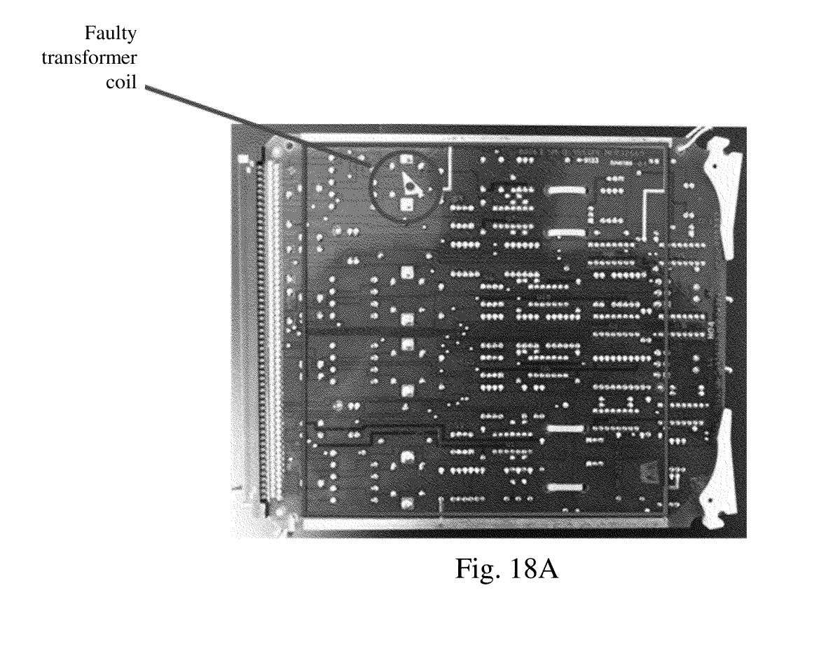

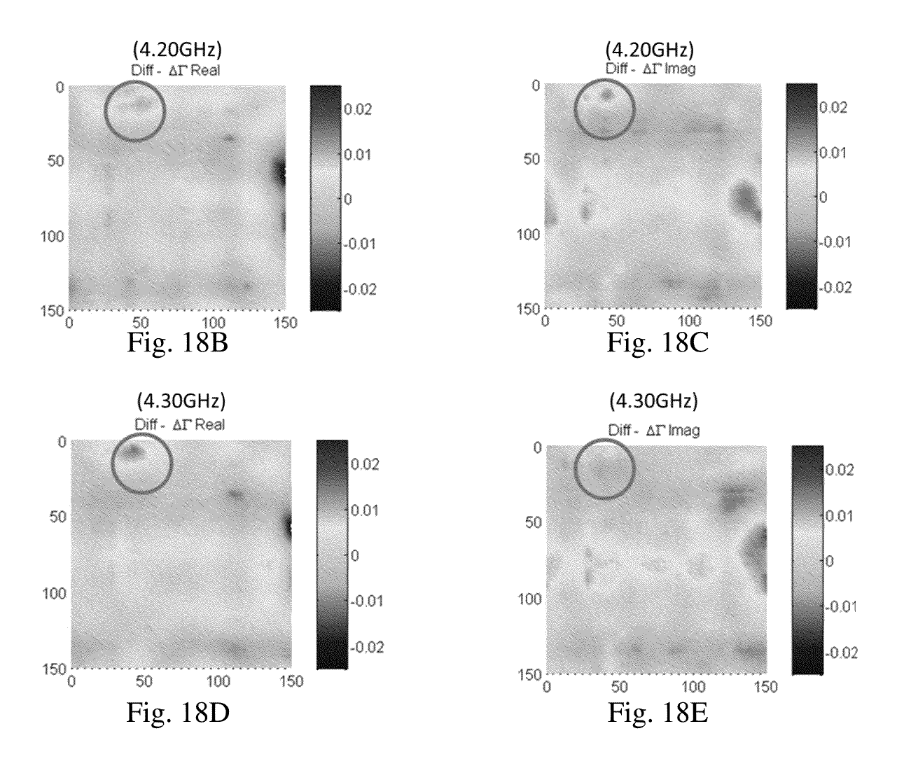

FIG. 18A is a photograph of a circuit card assembly including a fault introduced to a transformer coil. FIGS. 18B-18E are graphs of the reflection coefficient scan data for the circuit card assembly of FIG. 18A which show a corresponding difference between the scan and reference scans indicative of the location of the faulty transformer coil. This experiment confirms it is possible to highlight areas of a circuit card assembly to report differences in the topology or component structure, including defects inside of the components.

Example: Calculated Reflection Coefficients

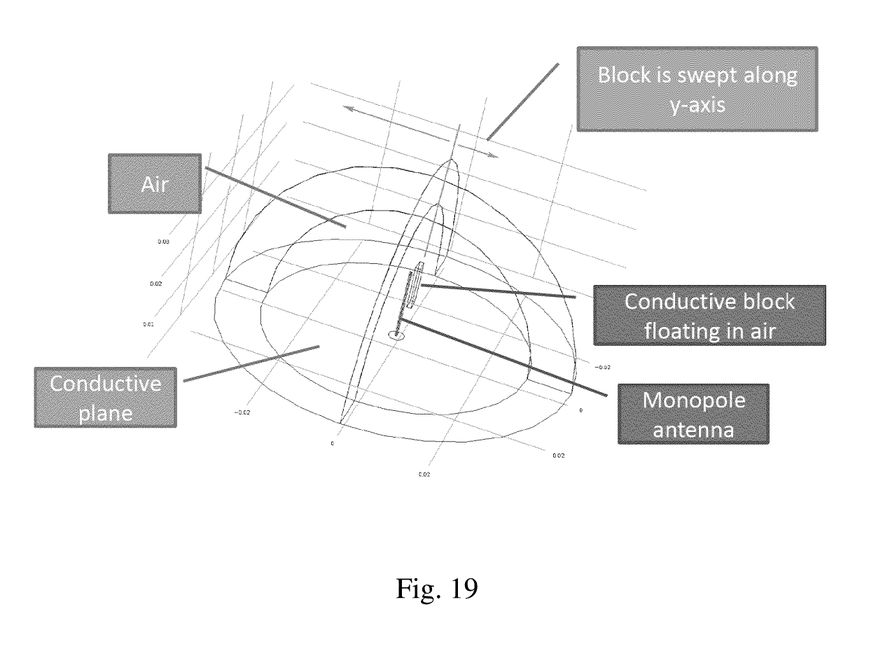

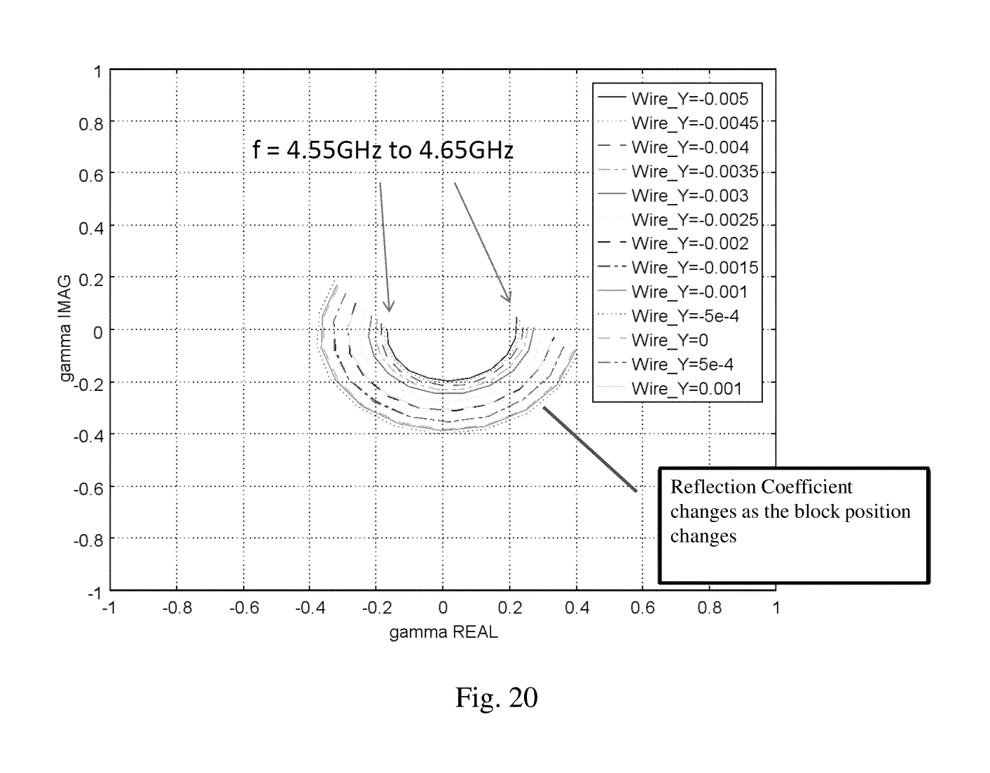

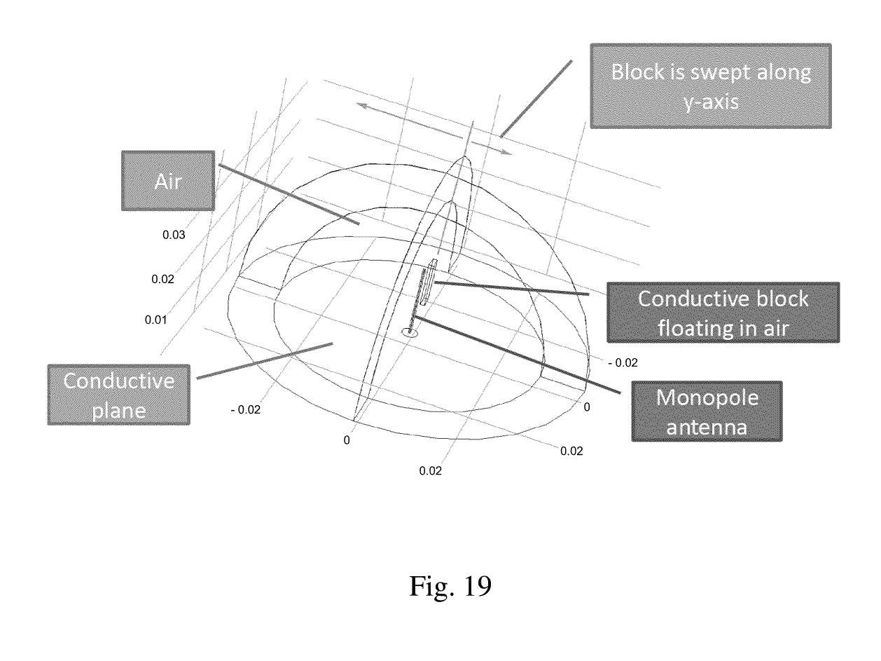

FIG. 19 is a schematic representation of a monopole antenna simulation model. The antenna impedance is measured in the model and used to calculate the reflection coefficient (Γ). Zₐₙₜ=Zₒ (50Ω) was assumed for an ideal quarter wavelength monopole antenna. The following equations were used for determining the graph of reflection coefficients for different Y positions shown in FIG. 20.

$${z}_{T} = \frac{{Z}_{ant}}{{Z}_{0}}$$

$$Γ = \frac{{z}_{T} - 1}{{z}_{T} + 1}$$

In view of the reflection coefficients presented in FIG. 20, the reflection coefficient changes as the block position changes.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art. Accordingly, the foregoing description and drawings are by way of example only.

What is claimed is:

1. A system comprising:
one or more electromagnetic field generators configured to generate an electromagnetic field proximate to a circuit;
one or more electromagnetic field sensors configured to scan the circuit by detecting an electromagnetic field induced in the circuit;
a computing device configured to receive the scan of the circuit and compare the scan to a reference scan of the circuit to determine whether the circuit is different from the reference scan.

2. The system of claim 1, further comprising a display, wherein the computing device is configured to indicate the difference of the scan of the circuit from the reference scan on the display.

3. The system of claim 1, wherein the difference indicates a fault.

4. The system of claim 1, further comprising a database including the reference scan of the circuit, wherein the computing device retrieves the reference scan from the database.

5. The system of claim 1, further comprising a translation system configured to translate the one or more electromagnetic field sensors relative to the circuit to scan the circuit.

6. A system comprising:
an electromagnetic field generator configured to generate an electromagnetic field proximate to a circuit to induce an electromagnetic field in a conductive portion of the circuit;
an electromagnetic field sensor configured to scan the circuit by detecting the induced electromagnetic field;
an imaging device configured to image the circuit; and
a computing device configured to receive the image of the circuit from the imaging device, and wherein the computing device is configured to compare the image to a reference image to identify the circuit.

7. The system of claim 6, further comprising a display, wherein the computing device is configured to indicate the difference of the scan of the circuit from the reference scan on the display.

8. The system of claim 6, wherein the difference indicates a fault.

9. The system of claim 6, further comprising a database including the reference scan of the circuit, wherein the computing device retrieves the reference scan from the database.

10. The system of claim 6, further comprising a translation system configured to translate the one or more electromagnetic field sensors relative to the circuit to scan the circuit.

11. A method comprising:
generating an electromagnetic field proximate to a circuit to induce an electromagnetic field in a conductive portion of the circuit;
scanning the circuit by detecting the induced electromagnetic field;
comparing the scan to a reference scan of the circuit to determine whether the circuit is different from the reference scan.

12. The method of claim 11, further comprising displaying the difference of the scan of the circuit from the reference scan on a display.

13. The method of claim 11, wherein the difference indicates a fault.

14. The method of claim 11, further comprising retrieving the reference scan from a database prior to comparing the scan to the reference scan.

15. The method of claim 11, further comprising translating one or more electromagnetic field sensors relative to the circuit to scan the circuit.

16. A method comprising:
generating an electromagnetic field proximate to a circuit to induce an electromagnetic field in a conductive portion of the circuit;
scanning the circuit by detecting the induced electromagnetic field;
imaging the circuit; and
comparing the image to a reference image to identify the circuit.

17. The method of claim 16, further comprising treating a reference scan based on the identified circuit.

18. The method of claim 16, compare fault wherein the difference indicates a fault.

19. The method of claim 16, further comprising retrieving the reference image from a database prior to comparing the image to the reference image.

20. The method of claim 16, further comprising translating one or more electromagnetic field sensors relative to the circuit to scan the circuit.
